(19) United States
(12) Patent Application Publication
(10) Pub. No.: US 2006/0028197 A1
(43) Pub. Date: Feb. 9, 2006

(54) Direct current offset cancellation and phase equalization for power metering devices

(75) Inventor: Vincent Quiquempoix, Divonne les Bains (FR)

Correspondence Address: Baker Botts L.L.P.;One Shall Plaza, 910 Louisiana, Houston, TX, 77002-4995, US

(73) Assignee: Microchip Technology Incorporated

(21) Appl. No.: 11/028,381

(22) Filed: Jan. 3, 2005

Related U.S. Application Data
(60) Provisional application No. 60/599,282, filed on Aug. 5, 2004.

(51) Int. Cl. G01R 11/32

(52) U.S. Cl. 324/142

(57) ABSTRACT

A power metering device having direct current offset cancellation and phase equalization between the voltage and current channels by using two high-pass filters, one for each channel, and further removing the ω(2πf) component of the power term for less critical low-pass filter design.

### RELATED PATENT APPLICATION

This application claims priority to commonly owned U.S. Provisional Patent Application Ser. No. 60/599,282; filed Aug. 5, 2004; entitled “Direct Current Offset Cancellation And Phase Equalization For Power Metering Devices,” by Vincent Quiquempoix, which is hereby incorporated by reference herein for all purposes.

### TECHNICAL FIELD OF THE INVENTION

The present invention relates to electronic power metering, more particularly, to direct current offset cancellation and phase equalization in a power metering device.

### BACKGROUND OF THE RELATED TECHNOLOGY

In power metering or measurement systems, measured analog current and voltage channels are often digitized for ease in performing digital signal processing on the voltage and current information so as to produce a more accurate power measurement than could be obtained from a completely analog power metering system. However, the analog electronics of the power metering system and the analog-to-digital converters (“ADC”) for each channel (current and voltage), may introduce some signal offset that can create an error in the evaluation of the resulting calculated product of the current and voltage measurements (power), thus there may be an error in the power measurement. Removal of this signal offset without creating additional error components or have the ability compensate or calibrate out an error term is desired so that the power measurement is accurate. However, there may still remain a problem of introducing a phase error in the measurement of voltage and current that cannot be cancelled out or a gain error in one or both measurement channels than cannot be calibrated.

Present technology may have one of the two channels (either voltage or current) in the power meter system that includes a high-pass filter (“HPF”) and a phase compensation block. The HPF will remove any direct current (“DC”) offset of the signal while the phase compensation block may be used to compensate for the phase difference induced by the HPF. However, phase is not perfectly compensated over all frequencies of interest, thus the power metering system is only accurate over a limited frequency bandwidth where the phase compensation is accurate enough to meet the desired precision of the metering specification.

### SUMMARY OF THE INVENTION

The present invention overcomes the above-identified problems as well as other shortcomings and deficiencies of existing technologies by providing an offset cancellation apparatus, system and method for power metering applications having inherent phase equalization between channels by using two high-pass filters, one for each channel (voltage and current). DC offset is removed from either or both channels of the alternating current (“AC”) power measurement system without introducing phase difference errors between the two measurement channels (voltage and current). In addition, the present invention may also remove the ω(2πf) component of the power term which relaxes the design constraints for the low-pass filters.

A technical advantage of the present invention is that phase matching between the two channels is inherent because the high-pass filters of the same design may be used for each of the two channels (voltage and current). This results in maintaining substantially zero phase difference throughout the entire frequency range of operation, thus limiting operating frequency bandwidth to ensure the accuracy of the measurement is no longer required. Also, reducing the criticality of phase response over frequency relaxes design complexity of the high-pass filter.

According to a specific exemplary embodiment of the invention, using two high-pass filters with matched phase responses, one high-pass filter (HPF) for each of the two channels (voltage and current), reduces the design constraints since each channel may have different gains and the prior art requirement of using an additional phase compensation block is no longer needed. Thus, relaxed requirements for the channel high-pass filters reduces the required design time. Additional benefits are the gain error term at the output of the multiplier is now a function of only one variable (the gain of the HPF) which relaxes the design constraints on the HPF. The gain error term is now the square of the HPF gain for the measured frequency which defines the constraints on the HPF design. Moreover, there is no more ω component in the output product which makes the low-pass filter (“LPF”) easier to design since only the 2ω component need be reject.

Other technical advantages should be apparent to one of ordinary skill in the art in view of what has been disclosed herein.

### BRIEF DESCRIPTION OF THE DRAWINGS

A more complete understanding of the present disclosure and advantages thereof may be acquired by referring to the following description taken in conjunction with the accompanying drawings wherein:

FIG. 1 is a schematic block diagram of a power metering device, according to a specific exemplary embodiment of the invention; and

FIG. 2 is a schematic block diagram of a power measurement system using the power metering device depicted in FIG. 1.

The present invention may be susceptible to various modifications and alternative forms. Specific embodiments of the present invention are shown by way of example in the drawings and are described herein in detail. It should be understood, however, that the description set forth herein of specific embodiments is not intended to limit the present invention to the particular forms disclosed. Rather, all modifications, alternatives, and equivalents falling within the spirit and scope of the invention as defined by the appended claims are intended to be covered.

### DETAILED DESCRIPTION OF SPECIFIC EMBODIMENTS

Referring now to the drawings, the details of a specific exemplary embodiment of the present invention is schematically illustrated. Like elements in the drawings will be represented by like numbers, and similar elements will be represented by like numbers with a different lower case letter suffix.

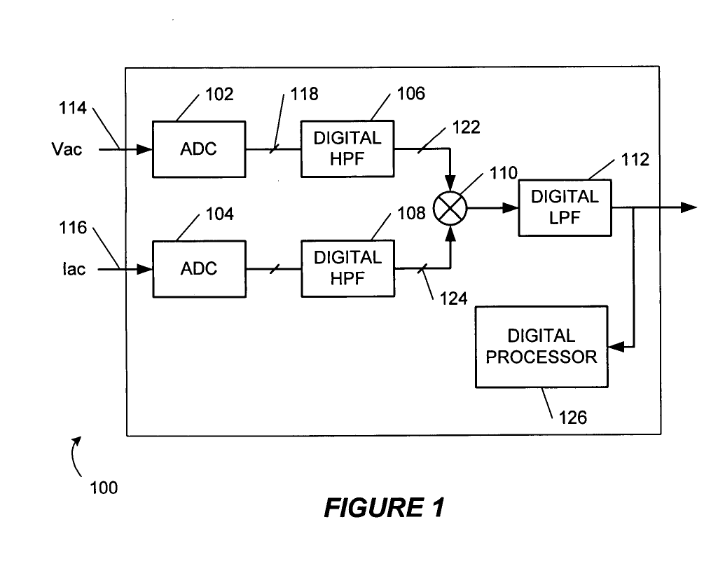

Referring to FIG. 1, depicted is a schematic block diagram of a power metering device, according to a specific exemplary embodiment of the invention. The power metering device, generally represented by the numeral 100, comprises a first analog-to-digital convert (ADC) 102, a second ADC 104, a first digital high pass filter (HPF) 106, a second digital HPF 108, a multiplier 110, and a digital low pass filter (LPF) 112. For power metering, direct current (DC) offset must be substantially reduced (canceled). The first and second ADCs 102 and 104 are preferably Sigma Delta ADCs, and preferably have substantially the same output data rates. However, a difference in output data rates may be compensated for by using a proper interpolation ratio between the two ADC outputs 118 and 120. The LPF 112 may follow the multiplier 110 for filtering of the error components as more fully described herein.

For example, alternating current (AC) voltage 114 and current 116 may have substantially the same frequency f, which is the typical power measurement condition, and if the ADCs 102 and 104 have substantially the same output data rate, the following equations are appropriate:
Vₙ=V cos(ωtₙ)+V
Iₙ=I cos(ωtₙ)+I_{off}
where I_{off} and V_{off} are offset components coming from the ADCs 102 and 104, and the system, ω=2πf, the pulsation of the inputs.

The product of these two outputs (118 and 120) may be evaluated for measuring the real power:

$${V}_{n} * {I}_{n} = \frac{VI}{2} + {V}_{off} {I}_{off} + ( {V}_{off} I + {I}_{off} V ) cos ( ω {t}_{n} ) + \frac{VI}{2} cos ( 2 ω {t}_{n} )$$

This product spectrum is the sum of a DC term evaluating the real power, an ω error term and a 2ω term representing the real power amplitude. In a power measurement we need to measure the real power quantity and be able to read it on the DC term for more convenience. However, with the standard structure, we can see that the DC term is the sum of the information we want to measure (VI/2) and a DC error term coming from the offset of the system. This offset term will create an error in the estimation of the real power term that needs to be canceled out in order to obtain an accurate measurement. This calculation has been performed with in-phase current and voltage inputs but can be done in the same way with signals that are not in phase. The real power term will then be V*I*cos φ instead of V*I.

Using only a single high-pass filter, e.g., (HPF 106) on the voltage channel, the voltage 122 has the following output:
HVₙ=V cos(ωtₙ+φ(jω))*|H(jω)|
where the transfer function H of the high-pass filter (HPF 106) is:
H(jω)=|H(jω)|*Exp(jφ(jω))
The product of the high-pass filtered output 122 and the current output 120 is represented by:

$$\begin{matrix}{HV}_{n} * {I}_{n} = \frac{VI}{2} * \vert H ( jω ) \vert * Cos ( φ ( jw ) ) + {I}_{off} V cos ( ω {t}_{n} + φ ( jw ) ) * \\ \vert H ( jω ) \vert + \frac{VI}{2} cos ( 2 ω {t}_{n} + φ ( jω ) ) * \vert H ( jw ) \vert\end{matrix}$$

This technique effectively cancels the offset term that was part of the DC component but has some drawbacks. There is still a ω component in the output spectrum which is dependent on the current channel offset. More importantly, the real power quantity being measured is now modulated by the gain and the phase of the single high-pass filter. The gain has little effect on the overall accuracy and can be maintained very close to one for the desired frequency ranges with adequate filter design. However, the phase must be compensated for because a very small difference in phase may create large errors on the output measurement. Phase is usually difficult to control and to equalize throughout a large frequency input range.

The present invention solves the phase problem by adding another high-pass filter (HPF 108) on the other channel (e.g., the current channel). Now the product term may be rewrite as follows:

$$\begin{matrix}{I}_{n}^{′} = \frac{VI}{2} * \vert {H}_{1} ( jω ) \vert * \vert {H}_{V} ( jω ) \vert * Cos ( {φ}_{1} ( jω ) - {φ}_{V} ( jω ) ) + \\ \frac{VI}{2} cos ( 2 ω {t}_{n} + {φ}_{V} ( jω ) + {φ}_{V} ( jω ) ) * \vert {H}_{1} ( jω ) \vert * \vert {H}_{V} ( jω ) \vert\end{matrix}$$

With HV and HI representing the HPF outputs 122 and 124 of the voltage and current channels, respectively.

The ω component is effectively cancelled out and the real power term is modulated by the product of the HPF 106 and HPF 108 gains, and the difference of their phase. If the two HPFs 106 and 108 have substantially the same phase response, the DC product term will only be modulated by the product of the two HPF gains which can be made very accurate by adequate filter design. Therefore, is substantially no more restrictions on the HPF filter design, e.g., the number of input bits (N1, N2) and the output bits (M1, M2) may be totally different. The HPF transfer functions may be arbitrarily chosen with the above defined limitations.

Furthermore, by having the same design for both HPFs 106 and 108. The product terms then become:

$${I}_{n}^{′} = \frac{VI}{2} * {\vert H ( jω ) \vert}^{2} + \frac{VI}{2} cos ( 2 ω {t}_{n} + 2 φ ( jw ) ) * {\vert H ( jω ) \vert}^{2}$$

Here the implementation becomes very easy, the HPF filter design constraint is that the gain squared is close to 1 for the desired bandwidth. This gain error term is very flat with adequate filter design and may even be calibrated out if necessary by external trimming. The design constraints become much more relaxed and the filtering of this product becomes easier because of the removed ω component.

DC power components may also be measured by removing the high-pass filters (HPFs 106 and 108) for both channels but in that case the DC offset terms are not canceled.

A digital processor 126 may be coupled to the output of the digital LPF 112. The digital processor 126 may perform the functions of the first and second digital HPFs 106 and 108, the multiplier 110 and the digital LPF 112. The digital processor 126 may be comprised of a microprocessor, microcontroller, digital signal processor (DSP), application specific integrated circuit (ASIC), programmable logic array (PLA), and the like. The digital device 100 may be fabricated, including the first and second ADCs 102 and 104, on an semiconductor integrated circuit die and this semiconductor integrated circuit die may be packaged in any type of integrated circuit package (not shown). It is contemplated and within the scope of the present invention that the semiconductor integrated circuit die may also be comprised of a plurality of semiconductor integrated circuit dice and may be packaged in a multiple die integrated circuit package.

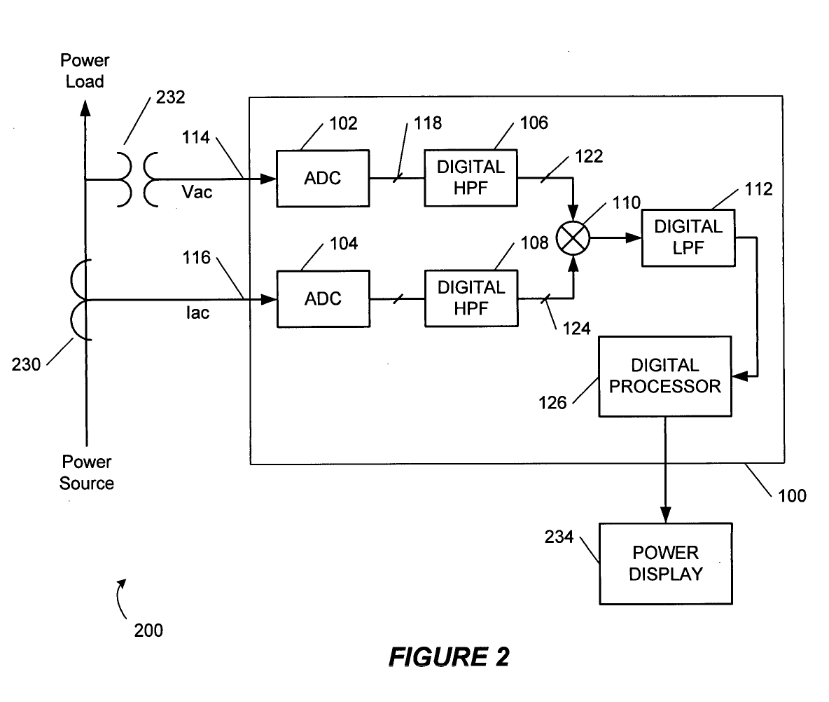

Referring now to FIG. 2, depicted is a power measurement system using the power metering device depicted in FIG. 1. A power measurement system, generally represented by the numeral 200, may comprise the digital device 100, a power meter display 234, a potential transformer (PT) 232 and a current transformer (CT) 230. The PT 232 is coupled to the input (114) of the ADC 102 and the CT 230 is coupled to the input (116) of the ADC 104. The power meter display 234 is coupled to the digital processor 126. The power meter display 234 may be part of a power management system (not shown).

It is contemplated and within the scope of the present invention that a plurality of voltage and current inputs may be utilized for measuring multiphase power, e.g., three phase power will may use three voltage ADCs and three current ADC, and/or analog multiplexers may be utilized so that the voltage and current ADCs may measure more than one value on a time shared basis. In addition, it is contemplated and within the scope of the invention that one ADC may be used in combination with an analog multiplexer to measure both voltage and current values on an alternate basis. It is also contemplated that the HPF 106 may be multiplexed (hardware and/or software) for filtering the plurality of outputs of the plurality of ADCs 102. Likewise, the HPF 108 may be software multiplexed for filtering the plurality of outputs of the plurality of ADCs 104. In addition, a single digital HPF may be multiplexed (hardware and/or software) for filtering the outputs of a plurality of ADCs. Once the analog values have been converted to digital values by a DAC(s), the digital values may stored and then processed by the digital processor 126 according to the teachings of the present invention.

The present invention has been described in terms of specific exemplary embodiments. In accordance with the present invention, the parameters for a device may be varied, typically with a design engineer specifying and selecting them for the desired application. Further, it is contemplated that other embodiments, which may be devised readily by persons of ordinary skill in the art based on the teachings set forth herein, may be within the scope of the invention, which is defined by the appended claims. The present invention may be modified and practiced in different but equivalent manners that will be apparent to those skilled in the art and having the benefit of the teachings set forth herein.

What is claimed is:

1. A power metering digital device having direct current offset cancellation and phase equalization, comprising:
a first analog to digital converter (ADC) having an analog input adapted for coupling to a first analog value, and a digital output representative of the first analog value;
a second ADC having an analog input adapted for coupling to a second analog value, and a digital output representative of the second analog value;
a first digital high pass filter (HPF) having an input coupled to the first ADC output;
a second digital HPF having an input coupled to the second ADC output;
a digital multiplier having a first input coupled to an output of the first digital HPF, a second input coupled to an output of the second digital HPF, and an output having a product of the first and second analog values; and
a digital low pass filter (LPF) having an input coupled to the output of the digital multiplier, and an output having a power value based upon the first and second analog values.

2. The digital device according to claim 1, wherein the first ADC is a Sigma Delta ADC.

3. The digital device according to claim 1, wherein the second ADC is a Sigma Delta ADC.

4. The digital device according to claim 1, wherein the first analog value is a voltage value.

5. The digital device according to claim 4, wherein the voltage value comprises an alternating current (AC) voltage.

6. The digital device according to claim 5, wherein the AC voltage has a direct current (DC) component.

7. The digital device according to claim 1, wherein the second analog value is a current value.

8. The digital device according to claim 7, wherein the current comprises an alternating current (AC).

9. The digital device according to claim 8, wherein the AC has a direct current (DC) component.

10. The digital device according to claim 1, further comprising a digital processor coupled to the output of the digital LPF.

11. The digital device according to claim 10, wherein the digital processor performs the first and second digital HPFs, digital multiplier and digital LPF functions.

12. The digital device according to claim 10, wherein the digital processor is selected from the group consisting of a microprocessor, microcontroller, digital signal processor (DSP), application specific integrated circuit (ASIC), and programmable logic array (PLA).

13. The digital device according to claim 1, wherein the first and second ADCs, the first and second digital HPFs, the digital multiplier and the digital LPF are fabricated on an integrated circuit die.

14. The digital device according to claim 13, wherein the integrated circuit die is enclosed in an integrated circuit package.

15. The digital device according to claim 13, wherein a digital processor is fabricated on the integrated circuit die.

16. The digital device according to claim 1, further comprising a plurality of first ADCs for measuring a plurality of first analog values, and a plurality of second ADCs for measuring a plurality of second analog values.

17. The digital device according to claim 1, further comprising a plurality of first HPFs coupled to the outputs of respective ones of the plurality of first ADCs and a plurality of second HPFs coupled to the outputs of respective ones of the plurality of second ADCs.

18. A power measurement system having direct current offset cancellation and phase equalization, said digital system comprising:
a digital device comprising,
a first analog to digital converter (ADC) having an analog input adapted for coupling to a first analog value, and a digital output representative of the first analog value;
a second ADC having an analog input adapted for coupling to a second analog value, and a digital output representative of the second analog value;
a first digital high pass filter (HPF) having an input coupled to the first ADC output;
a second digital HPF having an input coupled to the second ADC output;
a digital multiplier having a first input coupled to an output of the first HPF, a second input coupled to an output of the second digital HPF, and an output having a product of the first and second analog values; and
a digital low pass filter (LPF) having an input coupled to the output of the digital multiplier, and an output having a power value based upon the first and second analog values;
a power display coupled to the output of the digital LPF;
a voltage sensing device coupled to the analog input of the first ADC for producing the first analog value; and
a current sensing device coupled to the analog input of the second ADC for producing the second analog value.

19. The system according to claim 18, wherein the voltage and current sensing devices are coupled to a power source and power load.

20. The device according to claim 18, wherein the voltage sensing device is a potential transformer.

21. The system according to claim 18, wherein the current sensing device is a current transformer.

22. The system according to claim 18, further comprising a digital processor coupled to the output of the digital LPF.

23. The system according to claim 21, wherein the digital processor performs the first and second digital HPFs, digital multiplier and digital LPF functions.

24. The digital device according to claim 21, wherein the digital processor is selected from the group consisting of a microprocessor, microcontroller, digital signal processor (DSP), application specific integrated circuit (ASIC), and programmable logic array (PLA).

25. The system according to claim 18, wherein the digital device is fabricated on an integrated circuit die.

26. The system according to claim 25, wherein the integrated circuit die is enclosed in an integrated circuit package.

27. The system according to claim 25, wherein a digital processor is fabricated on the integrated circuit die.

28. A method for measuring power and having direct current offset cancellation and phase equalization, said method comprising the steps of:
converting a first analog value to a first digital value;
converting a second analog value to a second digital value;
high pass filtering the first digital value;
high pass filtering the second digital value;
multiplying the high pass filtered first and second digital values together to produce a product value; and
low pass filtering the product value to produce a power value.

29. The method according to claim 28, wherein the step of converting the first analog value to the first digital value is done with a Sigma Delta ADC.

30. The method according to claim 28, wherein the step of converting the second analog value to the second digital value is done with a Sigma Delta ADC.

31. The method according to claim 28, wherein the steps of high pass filtering, multiplying and low pass filtering are done with a digital processor.

32. The method according to claim 31, wherein the digital processor is selected from the group consisting of a microprocessor, microcontroller, digital signal processor (DSP), application specific integrated circuit (ASIC), and programmable logic array (PLA).
